(19) United States
(12) Patent Application Publication
(10) Pub. No.: US 2007/0072388 A1
(43) Pub. Date: Mar. 29, 2007

(54) Bottle-shaped trench and method of fabricating the same

(75) Inventors: Chuan-Chi Chen, Hinchu County (TW); Yang-Yao Su, Hsinchu City (TW)

Correspondence Address: BIRCH STEWART KOLASCH & BIRCH, PO BOX 747, FALLS CHURCH, VA, 22040-0747, US

(73) Assignee: ProMos Technologies Inc.

(21) Appl. No.: 11/267,163

(22) Filed: Nov. 7, 2005

(30) Foreign Application Priority Data
Sep. 27, 2005 (TW) 94133519

(51) Int. Cl. H01L 21/76

(52) U.S. Cl. 438/424; 438/426; 438/434

(57) ABSTRACT

Fabrication of a bottle-shaped trench is disclosed. A semiconductor substrate with a trench therein is provided. An ion-doped barrier layer is formed in the trench, exposing the upper portion surfaces of the sidewall of the trench. An ion implantation is performed on the upper portion surfaces of the sidewall of the trench to reduce the oxidation rate in the substrate near the upper portion of the trench. The ion-doped barrier layer is removed, exposing the lower portion and bottom surfaces of the sidewall of the trench. A thermal oxidation treatment is performed, forming an oxide layer on the surface of the trench. The thickness of the oxide layer on the upper portion of the sidewall surface is much thinner than that of the oxide layer on the lower portion of the sidewall surface or that of the bottom surface. A bottle-shaped trench is formed by removing the oxide layer.

### BACKGROUND

The present invention relates to a method of fabricating a trench, and more particularly to a method of fabricating a bottle-shaped trench.

The most popular capacitor typically used in DRAM memory cells comprises two conductive layers (electrode plates) and an insulating layer therebetween. The capacitance of the capacitor depends on the thickness of the insulating layer, the surface area of the electrode plate and the electronic properties of the insulating materials.

In recent years, the development of semiconductor memory devices has become highly integrated and has high packing density. The area occupied by a memory cell must be shrunk so that numerous memory cells can be packed onto the substrate. At the same time, an electrode plate with a surface area great enough to maintain capacitance is desirable, thus, a bottle-shaped trench is formed for a capacitor to create enough space for formation of an electrode plate. Accordingly, the surface area of the electrode plate is increased to increase capacitance while maintaining the small area occupied on the substrate surface.

U.S. Pat. No. 6,841,443 discloses a method for fabricating a deep trench capacitor for dynamic memory cells. The method comprises the following steps. A silicon substrate is provided with a trench formed therein. A thin mask layer, which can be selectively removed later with respect to the material of the substrate, is deposited on the inner surface of the trench and on the substrate surface. The preferred thin mask layer may be a stack comprising an oxide layer, a first silicon nitride layer, an α-Si layer and a second silicon nitride layer formed in sequence.

The coated trench is filled with a polymer layer, without any voids being left. The polymer layer is planarized as far as the substrate surface and is etched back to approximately the subsequent collar depth. Portions of the second silicon nitride layer, not masked by the polymer layer, are removed by means of selective anisotropic etching until the α-Si layer is exposed. The entire polymer layer is removed by means of wet-chemical etching, and the uncovered α-Si layer is oxidized by means of a thermal oxidation. Accordingly, the α-Si layer over the lower portion of the trench, covered by the second silicon nitride layer, is not oxidized. The overall thin mask layer remaining in the lower portion of the trench is removed selectively. Accordingly, the stacks of the oxide layer, the first nitride silicon layer and the oxidized α-Si layer over the upper portion of the trench serves as an etching mask layer in subsequent formation of a bottle-shaped trench. The silicon substrate at the lower portion of the trench is partially removed, preferably by wet etching, thus a bottle-shaped trench is formed.

However, the following problems exist in the described method. First, trench etching is getting difficult due to the continuously diminished cell dimension, especially removal of the nitride layer at the lower portion of the trench. Second, multiple steps for remove and formation of a liner or mask layer are required prior to formation of the bottle-shaped trench. Third, high complexity of process flow leads to increased cost.

Accordingly, a simple fabrication method of a bottle-shaped trench for a trench capacitor is desirable.

### SUMMARY

An embodiment of the invention provides a simple fabrication method of a bottle-shaped trench. The method precisely controls the oxidation growth or the consumption of substrate through an ion implant. Furthermore, depending on the depth of the ion-doped barrier layer, the bottle-shaped regions can be controlled and adjusted.

A method of fabricating a bottle-shaped trench comprises the following. A semiconductor substrate is provided. A trench is formed in the semiconductor substrate. An ion-doped barrier layer (or an ion implant barrier layer) is formed in the trench, exposing the upper portion surfaces of the sidewall of the trench. An ion implantation is performed on the upper portion surfaces of the sidewall of the trench in order to reduce the oxidation rate in the substrate near the upper portion of the trench. The ion-doped barrier layer is removed, exposing the lower portion and bottom surfaces of the sidewall of the trench. A thermal oxidation treatment is performed, forming an oxide layer on the surface of the trench. The thickness of the oxide layer on the upper portion of the sidewall surface is much thinner than that of the oxide layer on the lower portion of the sidewall surface or that of the bottom surface. A bottle-shaped trench is formed by removing the oxide layer.

In the described method, a bottle-shaped trench featuring employing a tilt implant with filled potoresist or oxide as barrier layer and forming regions with various oxidation rate is provided.

A detailed description is given in the following embodiments with reference to the accompanying drawings.

### DESCRIPTION OF THE DRAWINGS

The invention can be more fully understood by reading the subsequent detailed description and examples with reference made to the accompanying drawings, wherein:

FIGS. 1 to 6 are cross-sections of a method of fabricating a bottle-shaped trench according to the present invention.

### DETAILED DESCRIPTION

One embodiment of the present invention provides a method of fabricating a bottle-shaped trench. The method comprises the following steps.

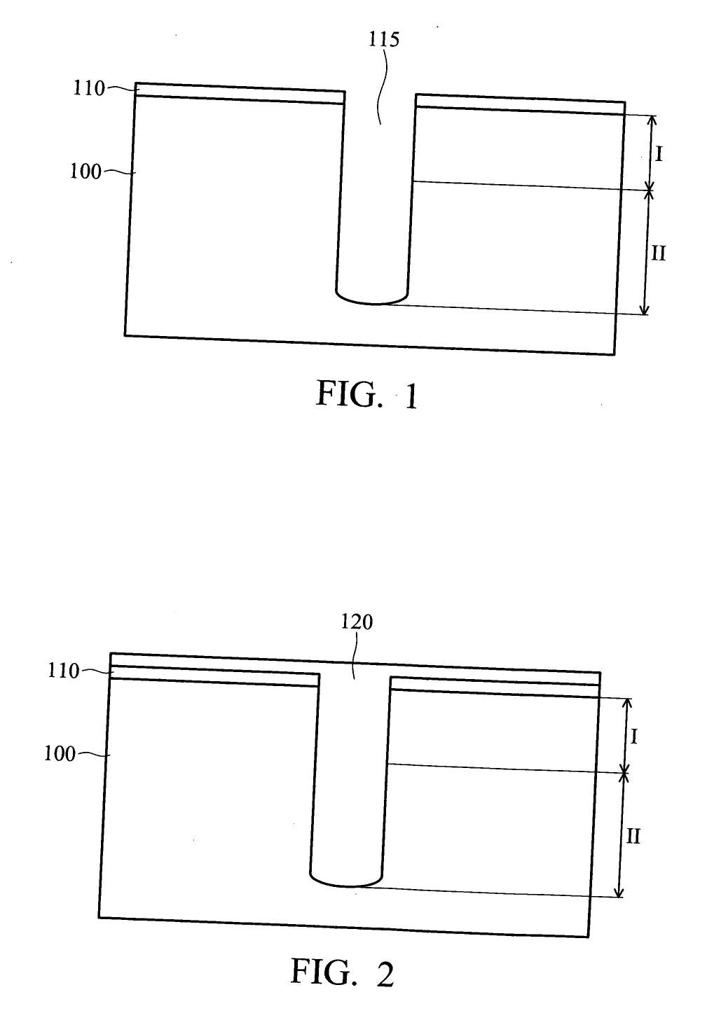

As shown in FIG. 1, a semiconductor substrate 100 such as a silicon substrate is provided. A dielectric layer 110 is formed on the semiconductor substrate 100. With the dielectric layer 110 serving as a hard mask, a deep trench 115 including regions I and II is formed by etching of the dielectric layer 110 and the semiconductor substrate 100. The dielectric layer 110 comprises an oxide layer, a nitride layer, or combinations thereof. Formation of the dielectric layer 110 comprises CVD, PVD, or thermal oxidation. Etching of the dielectric layer 110 comprises dry etching. In another embodiment, a photoresist material layer, serving as a masking layer of the dielectric layer 110 during patterning, maybe formed after formation of the dielectric layer 110.

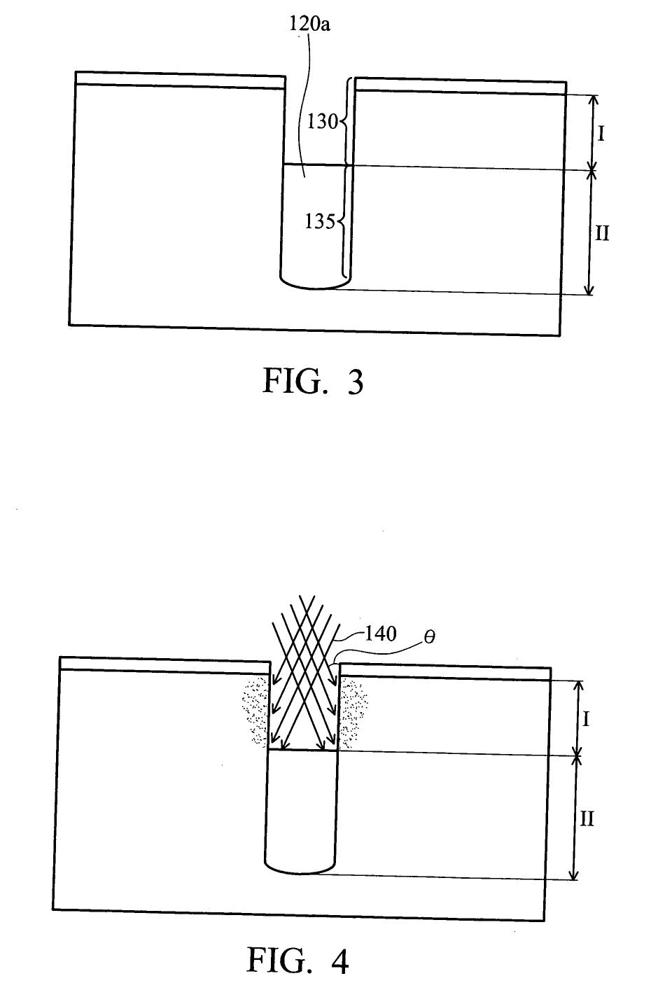

As shown in FIGS. 2 and 3, an ion implant barrier layer is formed over the deep trench 115. For example, the deep trench 115 is filled with a photoresist material 120 or silicon oxide which is recessed later, exposing the sidewalls 130 of the trench 150 over region I while the sidewalls 135 of the trench 150 over region II are covered by the residual photoresist material 120a or oxide silicon. Filling of the photoresist material 120 comprises spin coating. Preferably, TEOS (Tetraethylorthosilicate) formed by chemical vapor deposition is utilized to form oxide silicon. The photoresist material 120 comprises positive photoresist, negative photoresist, or antireflective coating. In one embodiment, while the photoresist material 120 serving as an ion implant barrier layer, the described recessing step comprises dry etching with CF₄ and O₂ serving as reactive gases. In another embodiment, while the oxide silicon serving as a material of the ion implant barrier layer, the described recessing step comprises dry etching with C₅F₈ and O₂ serving as reactive gases. In another embodiment, wet etching is utilized for recessing oxide silicon with a solution including HF and buffer HF. As shown in FIG. 4, with a photoresist material 120a serving as a barrier layer, a tilt ion implant 140 is performed on the sidewalls 130 over region I. The ion beam is injected into the substrate at an angle, preferably between 7 and 45 degrees, deviating from the normal line of the substrate surface. The doped ion beam, restraining oxidation, is generated from ion source gas comprising Ar, Ne, Xe, or N₂. The ion implant energy is between 10 and 200 keV. The ion implant dosage is between 10¹² and 10¹⁷ ions/cm². Due to doping of the inert ions into the exposed sidewalls 130 over region I, thus, low-active regions over the sidewalls 130 are formed. Accordingly, it is difficult to oxidize the low-active regions during the subsequent thermal oxidation.

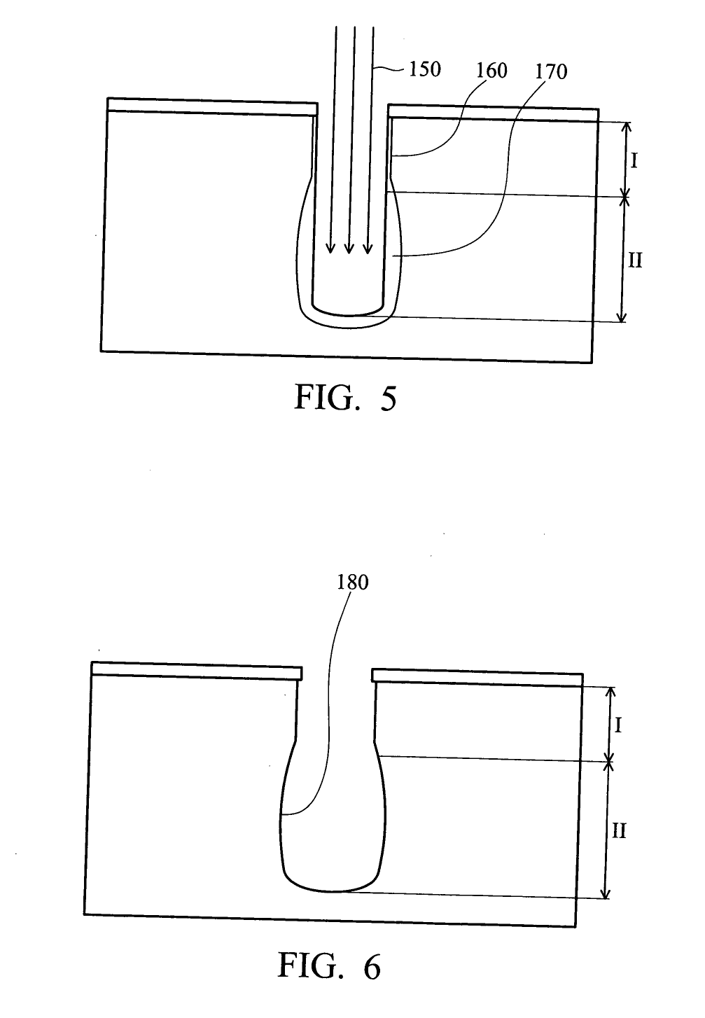

As shown in FIG. 5, stripping the photoresist material 120a, for example by means of wet etching, thus, the bottom surface and sidewalls over regions II of the trench 115 are exposed. Thereafter, the trench 115 is cleaned (not shown). The wet etching solvent may comprises H₂SO₄/H₂O/O₃, H₂SO₄/H₂O/H₂O₂, or the combinations thereof. In another embodiment, the etchant includes HF and buffer HF to remove oxide silicon.

Also referred to FIG. 5, a thermal oxidation 150 is performed on the interior of the trench 115, forming a thin oxide layer 160 on the sidewalls 130 over regions I and a thick oxide layer 170 on the undoped sidewalls 135 over regions II, respectively. The sidewalls 130 over regions I, a low-active region, has a relative oxidation rate lower than that of the undoped sidewalls 135 over regions II, a high-active region. The difference in oxidation rate leads to the difference in thickness between the oxide layers 160 and 170. The thermal oxidation 150 comprises dry oxidation, wet ox1idation, stream oxidation, or oxidation with Cl (chlorine). The thermal oxidation has an operating temperature between 800 and 1100° C. The thermal oxidation is performed for 5 to 60 minutes. The thermal oxidation 150 typically produces SiO₂.

As shown in FIG. 6, a bottle-shaped trench 180 is formed through removal of oxide on the sidewalls 130 over regions I and sidewalls 135 over regions II. Removal of the oxide layers 160 and 170 typically comprises wet etching utilizing HF and buffer HF as enchant.

As described, a bottle-shaped trench featuring employing a tilt implant with filled potoresist or oxide as a barrier layer and forming regions with various rates of oxidation is provided. Namely a simple fabrication method of bottle-shaped trench can be achieved by precisely controlling the oxidation growth or the consumption of substrate through an ion implant. Furthermore, depending on the recess depth in the barrier layer, the bottle-shaped regions can be controlled and adjusted.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method of fabricating a bottle-shaped trench, comprising:
providing a semiconductor substrate;
forming at least a trench in the semiconductor substrate;
forming an ion implant barrier layer in the trench, wherein upper sidewalls of the trench are exposed;
performing a tilt ion implant on the upper sidewalls of the trench, thus, oxidation of the upper sidewalls is restrained;
removing the ion implant barrier layer, thus a bottom surface and lower sidewalls of the trench are exposed;
performing a thermal oxidation to form an oxide layer over an interior of the trench, where the oxide layer over the upper sidewalls has a thickness less than that of the oxide layer over the lower sidewalls and the bottom surface; and
removing the oxide layer over the interior of the trench, forming the bottle-shaped trench.

2. The method as claimed in claim 1, wherein formation of the ion implant barrier layer comprises filling the trench with photoresist materials or oxide and recessing the photoresist materials or the oxide, exposing the upper sidewalls of the trench.

3. The method as claimed in claim 1, wherein the thermal oxidation comprises dry oxidation, wet oxidation, stream oxidation, or oxidation with Cl.

4. The method as claimed in claim 3, wherein the thermal oxidation has an operating temperature between 800 and 1100° C.

5. The method as claimed in claim 4, wherein the thermal oxidation is performed for 5 to 60 minutes.

6. The method as claimed in claim 1, wherein the ion implant includes ion source gas comprising Ar, Ne, Xe, or N₂.

7. The method as claimed in claim 6, wherein the ion implant energy is between 10 and 100 keV.

8. The method as claimed in claim 7, wherein the ion implant dosage is between 10¹² and 10¹⁷ ions/cm².

9. The method as claimed in claim 8, wherein the ion implant angle is between 7 and 45 degrees.

10. The method as claimed in claim 2, wherein recess of the photoresist materials comprises dry etching.

11. The method as claimed in claim 10, wherein the dry etching comprises CF₄ and O₂.

12. The method as claimed in claim 2, wherein recess of the oxide comprises dry etching.

13. The method as claimed in claim 12, wherein the dry etching comprises C₅F₈ and O₂.

14. The method as claimed in claim 1, wherein removal of the oxide layer comprises wet etching.
